(19) United States
(12) Patent Application Publication
(10) Pub. No.: US 2024/0265164 A1
(43) Pub. Date: Aug. 8, 2024

(54) METHOD FOR DETERMINING TOOTH MAGNETIC FLUX DENSITY RATIO AND OPTIMAL SPLIT RATIO OF MOTOR

(71) Applicant: HUAZHONG UNIVERSITY OF SCIENCE AND TECHNOLOGY, Wuhan, Hubei (CN)

(72) Inventors: Yawei WANG, Wuhan, Hubei (CN); Yuhang CHENG, Wuhan, Hubei (CN); Ronghai QU, Wuhan, Hubei (CN)

(21) Appl. No.: 18/695,934

(22) PCT Filed: Mar. 15, 2022
(86) PCT No.: PCT/CN2022/080819

§ 371 Date: Mar. 27, 2024

(30) Foreign Application Priority Data
Nov. 17, 2021 (CN) 202111360354.3

(51) Int. Cl. G06F 30/17; H02K 19/10

(52) U.S. Cl. CPC G06F 30/17; G06G 7/62; H02K 19/103

(57) ABSTRACT

The present invention discloses a method for determining a tooth magnetic flux density ratio and an optimal split ratio of a motor, relating to the field of motor design. The method includes: under the condition that different numbers of series turns per slot are given, performing analytic calculation to acquire a plurality of stator slot area and current density curves with a motor split ratio being an independent variable; using a magnetic flux density ratio to acquire tooth and yoke thicknesses of a motor when at different split ratios, acquiring a model of the motor, and then performing finite element simulation on the motor model to acquire a plurality of average torque curves with the motor split ratio being an independent variable; acquiring a motor split ratio corresponding to the maximum value of each average torque curve, and substituting the same into a corresponding current density curve to acquire current density at maximum average torque for the different number of series turns per slot; and acquiring a motor split ratio when maximum current density is not exceeded and the average torque is at maximum, and using the same as the optimal split ratio of the motor. In the present invention, the optimal split ratio of a motor is rapidly and accurately determined by means of finite element simulation in combination with analytic calculation.

### TECHNICAL FIELD

The present invention relates to the field of motor design and, more specifically, relates to a method for determining a tooth magnetic flux density ratio and an optimal split ratio of a motor.

### BACKGROUND ART

Motors being highly efficient while saving energy has become the focus of attention of the whole of society. According to statistics, power consumption of motors accounts for approximately 64% of the total power consumption of the whole of society. With the rapid development of new energy vehicles and other emerging industries, the coverage of motors in daily life, industry, and other fields is still rising steadily. The huge market demand and policy requirements on energy conservation and emission reduction have not only brought new vitality to the motor market, but have also raised new challenges with regard to their efficient operation. Therefore, development of high-efficiency motors is of great significance to promoting energy conservation and emission reduction and achieving green economic development in China.

In terms of conventional asynchronous motors, whether it's squirrel-cage motors or wound motors, Joule loss caused by the rotor current makes it difficult to further improve their efficiency, and thus failing to meet requirements for high efficiency and energy conservation. No squirrel cage structure is present on the rotor of a synchronous reluctance motor, thereby significantly reducing the loss of the rotor and improving the efficiency of the motor. The permanent magnet is added to the rotor of a permanent magnet motor, thereby significantly increasing torque density, and also alleviating the defect of synchronous reluctance motors that the power factor is low because of only one-sided excitation of stator windings. Therefore, in many industrial fields, conventional asynchronous motors are gradually replaced by synchronous reluctance motors or permanent magnet motors.

In general, when replacing products having the same frame size, conventional asynchronous motor stators are often used. However, since different types of motors have different structures, working principles, and degrees of magnetic circuit saturation, the size of the stator and rotor of the motor needs to be redesigned to maximize the advantages of the new motor topology. In this regard, selection of the motor split ratio (i.e., the ratio of the internal diameter to the external diameter of a stator) is particularly important, and affects torque very obviously. Conventional motor split ratio calculation methods mostly rely on analytic formulas to establish an expression between torque and the motor split ratio. However, for synchronous reluctance motors or permanent magnet motors, local saturation of the stator and rotor thereof is severe, affecting the accuracy of torque calculation results, and the optimal split ratio obtained from analytic calculation is usually not the actual optimal value, thereby often failing to meet design requirements. Moreover, stator yoke thickness and tooth width both change as the motor split ratio changes, and the slot area and stator copper loss of the motor change accordingly, and so there is no guarantee that the temperature rise of windings will still meet design requirements under the same cooling conditions, and verification is needed, causing the entire design process to be very complex.

### SUMMARY OF THE INVENTION

In view of the defects and improvement requirements of the prior art, the present invention provides a method for determining a tooth magnetic flux density ratio and an optimal split ratio of a motor, the objective thereof being to rapidly and accurately determine the optimal split ratio of a motor by means of finite element simulation in combination with analytic calculation.

To achieve the above objective, according to the first aspect of the present invention, provided is a method for determining a tooth magnetic flux density ratio of a motor, the motor being a slotted-stator radial magnetic flux alternating current motor, the method comprising:
S1, under the premise that stator copper loss is fixed, acquiring a stator slot area expression in which a motor split ratio is an independent variable;
S2, acquiring a stator slot area expression in which stator yoke thickness and a tooth width are independent variables, acquiring a stator yoke thickness expression in which the motor split ratio and the tooth magnetic flux density ratio are independent variables, and acquiring a tooth width expression in which the motor split ratio and the tooth magnetic flux density ratio are independent variables;
S3, substituting the stator yoke thickness expression and the tooth width expression acquired in step S2 into step S2 to acquire the stator slot area expression, and sorting by descending power according to the tooth magnetic flux density ratio, to acquire a stator slot area expression in which the motor split ratio and the tooth magnetic flux density ratio are independent variables; and
S4, when the motor split ratio is given, using an expression between a stator slot area and the motor split ratio acquired in step S1 under the condition that the stator copper loss is fixed so as to calculate a corresponding stator slot area, and then substituting the same into the stator slot area expression in which the motor split ratio and the tooth magnetic flux density ratio are independent variables acquired from step S3, to inversely acquire the tooth magnetic flux density ratio.

Preferably, in step S1, the calculation formula of the stator slot area is as follows:

$${S}_{slot} = \frac{{ρ}_{C u} ( {L}_{stk} + k \frac{π {D}_{e} χ}{2 p} ) {( {n}_{c s} \hat{I} )}^{2} {Q}_{s}}{2 {P}_{Cu} {k}_{fill}}$$

where Î represents stator phase current amplitude, n_{cs} represents the number of series turns per slot, Sₛₗₒₜ represents the stator slot area, ρcᵤ represents resistivity of copper, Lₛₜₖ represents the length of stack lamination, k represents the ratio of the length of an end winding to pole pitch, k being 1.5-1.7 for distributed winding, and k being \sqrt{2} for fractional slot concentrated winding, Dₑ represents the external diameter of a stator, χ represents the motor split ratio, p represents the number of pole-pairs of the motor, Qₛ represents the number of stator slots, Pcᵤ represents the stator copper loss, and k_{fill} represents the slot fill factor.

Beneficial effects: with regard to existing motor split ratio optimization solutions often needing to consider the problem of trade-off between average torque and efficiency and ignoring different winding temperature rises caused by different corresponding stator current densities at different motor split ratios, in the present invention, the stator copper loss of a motor is regarded as a constant, and the expression of the stator slot area related to the motor split ratio is derived according to this, thereby acquiring a curve of the current density changing with the motor split ratio. The stator copper loss is constant, and the total loss of the motor remains substantially unchanged, therefore during implementation, only whether the average torque of the motor is optimal needs to be considered, and further consideration of motor efficiency is not required.

Preferably, the calculation formula of the tooth magnetic flux density ratio β is as follows:

$$β = \frac{- {f}_{b} - \sqrt{{f}_{b}^{2} - 4 {f}_{a} {f}_{c}^{′}}}{2 {f}_{a}}$$

$${f}_{c}^{′} = {f}_{c} - \frac{4 {Q}_{s}}{π {D}_{e}^{2}} {S}_{slot}$$

where fₐ represents a coefficient of the second power, f_{b} represents a coefficient of the first power, and f_{c} represents a constant term.

Beneficial effects: in view of the fact that in the prior art, during the design of the shape and size of a stator slot, a stator tooth magnetic flux density value often needs to be preliminarily selected by referring to previous design experience, and the initial value usually needs adjusting when the split ratio of a motor is changed, resulting in a complex calculation process, in the present invention, the tooth magnetic flux density ratio is expressed as a function of the motor split ratio and the stator slot area, and the one-to-one correspondence between the motor split ratio and the stator slot area has been acquired under the condition that the stator copper loss is fixed, and thus the tooth magnetic flux density ratio is rapidly determined.

To achieve the above objective, according to the second aspect of the present invention, provided is a method for determining an optimal split ratio of a motor, the motor being a slotted-stator radial magnetic flux alternating current motor, the method comprising:
S1, under the condition that different numbers of series turns per slot are given, performing analytic calculation to acquire a plurality of current density curves with a motor split ratio being an independent variable, each curve corresponding to one number of series turns per slot, and performing finite element simulation on a motor model to acquire a plurality of average torque curves with the motor split ratio being an independent variable, each curve corresponding to one number of series turns per slot;
S2, acquiring a motor split ratio corresponding to a maximum value of each average torque curve, and substituting the same into a corresponding current density curve to acquire current density at maximum average torque for the different number of series turns per slot; and
S3, acquiring a motor split ratio when maximum current density is not exceeded and the average torque is at maximum, and using the same as the optimal split ratio of the motor.

Preferably, the calculation formula of current density J is as follows:

$$J = \frac{{n}_{c s} \hat{I}}{\sqrt{2} {S}_{slot} {k}_{fill}}$$

where Î represents stator phase current amplitude, n_{cs} represents the number of series turns per slot, Sₛₗₒₜ represents stator slot area, and kill represents the slot fill factor.

Preferably, the average torque curve with the motor split ratio being the independent variable is acquired by the following means:
(1) the number of series turns per slot being given, using the method according to the first aspect to acquire a tooth magnetic flux density ratio corresponding to the number of series turns per slot;
(2) substituting the tooth magnetic flux density ratio and a given motor split ratio into a stator yoke thickness expression and a tooth width expression, to acquire a stator yoke thickness and tooth width corresponding to the motor split ratio at the number of series turns per slot;
(3) establishing a corresponding motor model according to the stator yoke thickness and tooth width corresponding to the motor split ratio at the number of series turns per slot, performing finite element simulation, and performing post-processing to acquire an average torque value corresponding to the motor model; and
(4) changing the motor split ratio, and repeating steps (2) and (3) to acquire the average torque curve with the motor split ratio being the independent variable for the number of series turns per slot.

Beneficial effects: in the present invention, a parametric model of the motor is established. The stator yoke thickness and the tooth width of the motor are automatically adjusted as the motor split ratio changes, so that motor modeling and post-processing are rapid.

Preferably, the given different numbers of series turns per slot are determined by the following means:

(1) determining a base number of the number of series turns per slot according to motor phase voltage U:

$${n}_{c s}^{*} = \frac{Um}{\sqrt{2} π {fQ}_{s} {k}_{N 1} {Φ}_{1}}$$

where m represents the motor phase number, f represents frequency, Qₛ represents the number of stator slots, k_{N1} represents the winding factor, and Φ₁ represents magnetic flux per pole;
(2) determining the change step size of the number of series turns per slot: for a single-layer winding, the value of the change step size is 1/a, and for a double-layer winding, the value of the change step size is 2/a, where a represents the number of parallel paths of the winding; and
(3) for the base number of the number of series turns per slot, fluctuating the same according to the determined change step size, so as to determine a value range of the number of series turns per slot.

Beneficial effects: the existing problem in which the range of variation of the number of series turns per slot is unknown causes the amount of calculation of finite element simulation to be overly large. In the present invention, the number of series turns per slot is associated with phase voltage, and the number of series turns per slot is preliminarily determined, thereby determining the range and the step size of the number of series turns per slot, and reducing the calculation time of finite element simulation.

To achieve the above objective, according to the third aspect of the present invention, provided is a computer-readable storage medium, comprising a stored computer program, wherein when executed by a processor, the computer program controls a device in which the computer-readable storage medium is located to perform the method for determining a tooth magnetic flux density ratio of a motor according to the first aspect, or to perform the method for determining an optimal split ratio of a motor according to the second aspect.

In general, the above technical solutions proposed in the present invention can achieve the following beneficial effects:

(1) In the prior art, before designing the shape and size of a stator slot, the stator yoke and tooth magnetic flux density of the motor need to be preliminarily selected according to previous design experience. The stator yoke thickness and the tooth width are calculated according to estimated values, and magnetic circuit calculation and performance calculation are performed. When selection of the motor split ratio is changed, air gap magnetic flux density inside the motor changes accordingly. It is often difficult to achieve the previously selected stator yoke and tooth magnetic flux density from the stator yoke thickness and tooth width acquired according to the estimated values, and adjusting the initially selected value is also required, so as to re-calculate the performance. The calculation process is complex. In the present invention, the stator yoke thickness and the tooth width are expressed as the functional relationship between the motor split ratio and the tooth magnetic flux density ratio, and the tooth magnetic flux density ratio establishes the relationship between the stator yoke and tooth magnetic flux density and the air gap magnetic flux density, thereby effectively avoiding the above problem. Then, the expression of the stator slot area of the motor related to the motor split ratio and the tooth magnetic flux density ratio is acquired by using the stator yoke thickness and the tooth width. Under the premise that the stator copper loss is the same, the stator slot areas corresponding to different motor split ratios are acquired, thereby rapidly determining the tooth magnetic flux density ratio and the corresponding stator yoke thickness and tooth width.

(2) Existing methods for calculating a motor split ratio often rely on an analytic formula to establish the functional relationship between torque and the split ratio. However, the problem of local saturation of the stator and rotor is generally present in the motor, and the magnetic voltage drop on the iron core cannot be ignored, thereby weakening the air-gap magnetic field. It is difficult for the analytic method to take into consideration the problem of local saturation, resulting in acquired torque results to be high, and it is difficult to meet high calculation precision requirements. In addition, the harmonic content of the air-gap magnetic field caused by slotting of the stator and rotor is high, but the amount of calculation in the analytic formula considers only fundamental wave components, thus ignoring other subharmonic content, and so it is difficult to acquire an accurate result by using the analytic formula. The present invention uses the technical means of combining finite element simulation and analytic calculation to take into consideration the effects of iron core saturation and harmonics, achieving rapid and precise determination of an optimal motor split ratio under maximum average torque.

### BRIEF DESCRIPTION OF THE DRAWINGS

FIG. 1 is a flowchart of a method for determining the optimal split ratio of a motor provided in the present invention.

FIG. 2 is a cross-sectional view of a synchronous reluctance motor per pole provided in the present invention.

FIG. 3 is a schematic diagram of a calculation of the area of a trapezoidal stator slot provided in the present invention.

FIG. 4 is the relationship between stator slot area and motor split ratio in a 48-slot 8-pole synchronous reluctance motor when the number of series turns per slot is respectively 3.5, 4, and 4.5 as provided in the present invention.

FIG. 5 is the relationship between average torque and current density following changes in motor split ratio in a 48-slot 8-pole synchronous reluctance motor when the number of series turns per slot is respectively 3.5, 4, and 4.5 as provided in the present invention.

FIG. 6 is a schematic diagram of a calculation of the area of a round-bottomed stator slot having sloping shoulders provided in the present invention.

### DETAILED DESCRIPTION

In order for the purpose, technical solution, and advantages of the present invention to be clearer, the present invention is described in further detail below with reference to the accompanying drawings and embodiments. It should be appreciated that the specific embodiments described here are used merely to explain the present invention and are not used to limit the present invention. In addition, the technical features involved in various embodiments of the present invention described below can be combined with one another as long as they do not constitute a conflict therebetween.

The present invention provides a method for determining a tooth magnetic flux density ratio of a motor, the motor being a slotted-stator radial magnetic flux alternating current motor, the method including:

Step S1, under the premise that stator copper loss is fixed (i.e., the total loss of the motor remains substantially unchanged), acquiring a stator slot area expression in which a motor split ratio is an independent variable.

Preferably, in step S1, the calculation formula of the stator slot area is as follows:

$${S}_{s l o t} = \frac{{ρ}_{C u} ( {L}_{s t k} + k \frac{π {D}_{e} χ}{2 p} ) {( {n}_{c s} \hat{I} )}^{2} {Q}_{s}}{2 {P}_{C u} {k}_{fill}} \qquad ( 1 )$$

where Î represents stator phase current amplitude, n_{cs} represents the number of series turns per slot, Sₛₗₒₜ represents the stator slot area, ρc_{N} represents resistivity of copper, Lₛₜₖ represents the length of stack lamination, k represents the ratio of the length of an end winding to pole pitch, k being 1.5-1.7 for distributed winding, and k being \sqrt{2} for fractional slot concentrated winding, Dₑ represents the external diameter of a stator, χ represents the motor split ratio, p represents the number of pole-pairs of the motor, Qₛ represents the number of stator slots, Pcᵤ represents the stator copper loss, and k_{fill} represents the slot fill factor.

Step S2, acquiring a stator slot area expression in which stator yoke thickness and tooth width are independent variables, acquiring a stator yoke thickness expression in which the motor split ratio and the tooth magnetic flux density ratio are independent variables, and acquiring a tooth width expression in which the motor split ratio and the tooth magnetic flux density ratio are independent variables.

Step S3, substituting the stator yoke thickness expression and the tooth width expression acquired in step S2 into step S2 to acquire the stator slot area expression, and sorting by descending power according to the tooth magnetic flux density ratio, to acquire a stator slot area expression in which the motor split ratio and the tooth magnetic flux density ratio are independent variables.

Step S4, when the motor split ratio is given, using an expression between a stator slot area and the motor split ratio acquired in step S1 under the condition that the stator copper loss is fixed so as to calculate a corresponding stator slot area, and then substituting the same into the stator slot area expression in which the motor split ratio and the tooth magnetic flux density ratio are independent variables acquired from step S3, to inversely acquire the tooth magnetic flux density ratio.

Preferably, the calculation formula of the tooth magnetic flux density ratio β is as follows:

$$β = \frac{- {f}_{b} - \sqrt{{f}_{b}^{2} - 4 {f}_{a} {f}_{c}^{′}}}{2 {f}_{a}} \qquad ( 2 )$$

$${f}_{c}^{′} = {f}_{c} - \frac{4 {Q}_{s}}{π {D}_{e}^{2}} {S}_{s l o t} \qquad ( 3 )$$

where fₐ represents a coefficient of the second power, f_{b} represents a coefficient of the first power, and f_{c} represents a constant term.

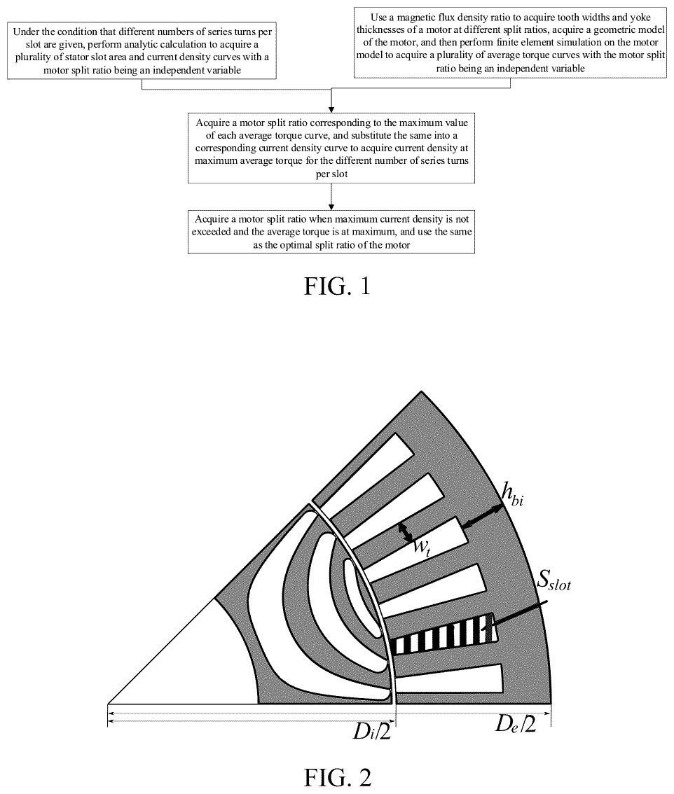

As shown in FIG. 1, the present invention provides a method for determining an optimal split ratio of a motor, the motor being a slotted-stator radial magnetic flux alternating current motor, the method including:

Step S1, under the condition that different numbers of series turns per slot are given, performing analytic calculation to acquire a plurality of stator slot area and current density curves with a motor split ratio being an independent variable, each curve corresponding to one number of series turns per slot, and performing finite element simulation on a motor model to acquire a plurality of average torque curves with the motor split ratio being an independent variable, each curve corresponding to one number of series turns per slot.

Preferably, the calculation formula of current density J is as follows:

$$J = \frac{{n}_{c s} \hat{I}}{\sqrt{2} {S}_{slot} {k}_{fill}} \qquad ( 4 )$$

where Î represents stator phase current amplitude, n_{cs} represents the number of series turns per slot, Sₛₗₒₜ represents stator slot area, and k_{fill} represents the slot fill factor.

Preferably, the average torque curve with the motor split ratio being the independent variable is acquired by the following means:
(1) the number of series turns per slot being given, using the above method to acquire a tooth magnetic flux density ratio corresponding to the number of series turns per slot;
(2) substituting the tooth magnetic flux density ratio and a given motor split ratio into a stator yoke thickness expression and a tooth width expression, to acquire a stator yoke thickness and tooth width corresponding to the motor split ratio at the number of series turns per slot;
(3) establishing a corresponding motor model according to the stator yoke thickness and tooth width corresponding to the motor split ratio at the number of series turns per slot, performing finite element simulation, and performing post-processing to acquire an average torque value corresponding to the motor model; and
(4) changing the motor split ratio, and repeating steps (2) and (3) to acquire the average torque curve with the motor split ratio being the independent variable for the number of series turns per slot.

Preferably, the given different numbers of series turns per slot are determined by the following means:

(1) determining a base number of the number of series turns per slot according to motor phase voltage U:

$${n}_{cs}^{*} = \frac{Um}{\sqrt{2} π {fQ}_{s} {k}_{N 1} {Φ}_{1}} \qquad ( 5 )$$

where m represents the motor phase number, f represents frequency, Qₛ represents the number of stator slots, k_{N1} represents the winding factor, and Φ₁ represents magnetic flux per pole.

Nₛ depends on the motor phase voltage U, and the calculation formula is as follows:

$$U = 4.44 {fNk}_{N 1} {Φ}_{1} = \frac{4.44 {fn}_{cs} {Q}_{s} {k}_{N 1} {Φ}_{1}}{m} \qquad ( 6 )$$

(2) Determining the change step size of the number of series turns per slot: for a single-layer winding, the value of the change step size is 1/a, where a is the number of parallel paths of the winding, and for a double-layer winding, the value of the change step size is 2/a.

The calculation formula of the number of series turns per slot is as follows:

$${n}_{cs} = \frac{{n}_{s}}{a} \qquad ( 7 )$$

where a is the number of parallel paths per phase, and for a single-layer winding, the maximum value thereof is equal to the number of pole-pairs. For a double-layer winding, the maximum value thereof is equal to the number of poles. Therefore, the change step size of n_{cs} is determined by the number of parallel paths per phase.

(3) For the base number of the number of series turns per slot, fluctuating the same according to the determined change step size, so as to determine a value range of the number of series turns per slot.

Step S2, acquiring a motor split ratio corresponding to a maximum value of each average torque curve, and substituting the same into a corresponding current density curve to acquire current density at maximum average torque for the different number of series turns per slot.

Step S3, acquiring a motor split ratio when maximum current density is not exceeded and the average torque is at maximum, and using the same as the optimal split ratio of the motor.

Using the 48-slot 8-pole synchronous reluctance motor having a stator having trapezoidal slots shown in FIG. 2 as an example, the internal diameter Dᵢ and external diameter Dₑ of the stator, the tooth width wₜ, the yoke thickness h_{bi}, and the stator slot area Sₛₗₒₜ are marked in the drawing.

The motor split ratio is defined as the ratio of the internal diameter to the external diameter of the stator:

$$χ = {D}_{i} / {D}_{e} \qquad ( 8 )$$

Torque of the motor may be expressed as:

$$T = \frac{π {D}_{i}^{2} {L}_{stk}}{4} {B}_{g} {K}_{s} \qquad ( 9 )$$

in the expression, Lₛₜₖ is the length of stack lamination of the motor, B_{g} is fundamental wave air gap magnetic flux density amplitude, and Kₛ is line current density, and can be further expressed as:

$${K}_{s} = \frac{{k}_{w} {Q}_{s} {n}_{cs} {I}^{\$}}{π {D}_{i}} \qquad ( 10 )$$

in the expression, k_{w} is a fundamental winding factor, Qₛ is the number of stator slots, n_{cs} is the number of series turns per slot, and Î is phase current amplitude.

Further, expression (10) is substituted into expression (9) to acquire a torque equation:

$$T = \frac{1}{4} {k}_{w} {Q}_{s} {n}_{c s} \hat{I} {B}_{g} {L}_{s t k} {D}_{e} χ \qquad ( 11 )$$

It can be found that when the external diameter of the stator of the motor is fixed, output torque is related to the value of the split ratio, and thus in order to optimize maximum torque, a suitable motor split ratio needs to be found.

Air gap magnetic flux:

$${Φ}_{g} = {B}_{g} π {D}_{i} {L}_{stk} \qquad ( 12 )$$

Stator tooth magnetic flux:

$${Φ}_{t} = {B}_{t} {Q}_{s} {w}_{t} {L}_{s t k} \qquad ( 13 )$$

Slot magnetic leakage is ignored, so that all air gap magnetic flux passes through the teeth, i.e., Φ_{g}=Φₜ. In addition, the magnetic flux density ratio β is defined as the ratio of the air gap magnetic flux density B_{g} to the stator tooth magnetic flux density Bₜ, and in this case, the tooth width may be expressed as:

$${w}_{t} = \frac{{B}_{g} π {D}_{i}}{{B}_{t} {Q}_{s}} = β \frac{π {D}_{e}}{{Q}_{s}} χ \qquad ( 14 )$$

Magnetic flux passing through the stator yoke is half of an air gap main magnetic flux:

$${Φ}_{bi} = {B}_{bi} {h}_{bi} {L}_{stk} = \frac{1}{2} {B}_{g} \frac{{D}_{i} {L}_{stk}}{p} \qquad ( 15 )$$

in the expression, p is the number of pole-pairs of the motor.

Expression (14) and expression (15) are combined to acquire the following stator yoke thickness expression:

$${h}_{bi} = \frac{1}{2 π} \frac{{Q}_{s}}{p} \frac{{B}_{t}}{{B}_{bi}} {w}_{t} = \frac{1}{2 π} \frac{{Q}_{s}}{p} α {w}_{t} = \frac{α β {D}_{e} χ}{2 p} \qquad ( 16 )$$

in the expression, α is defined as the ratio of tooth magnetic flux density to yoke magnetic flux density, and considering the knee point of a lamination of an iron core, α is a constant, and is approximately equal to 1.16.

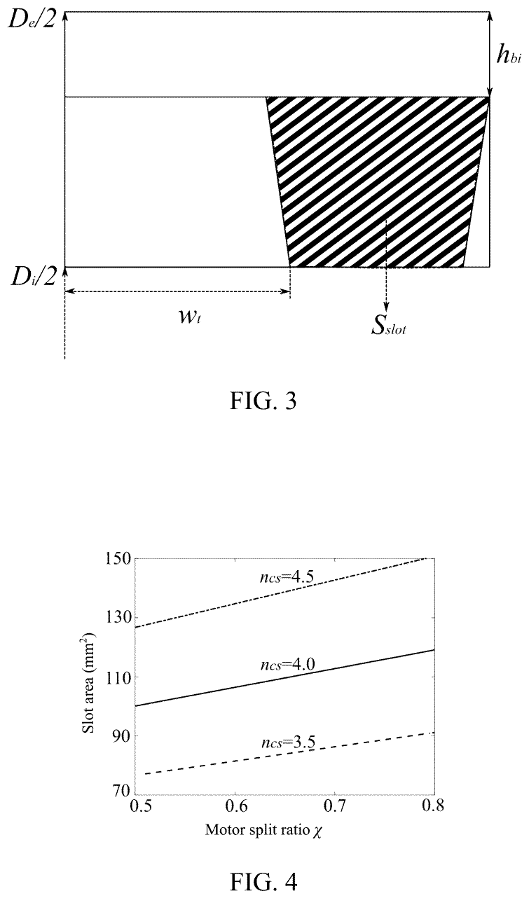

According to FIG. 3, the trapezoidal slot is simplified into a parallel slot, and the size of a slot wedge is ignored, so that the acquired stator slot area expression is:

$${S}_{slot} = \frac{{π ( {D}_{e} - 2 {h}_{bi} )}^{2} - π {D}_{i}^{2}}{4 {Q}_{s}} - \frac{{w}_{t} ( {D}_{e} - {D}_{i} - 2 {h}_{bi} )}{2} \qquad ( 17 )$$

Expression (14) and expression (16) are substituted into expression (17), and sorting is performed by descending power of β to acquire:

$${S}_{slot} = \frac{π {D}_{e}^{2}}{4 {Q}_{s}} ( {f}_{a} {β}^{2} + {f}_{b} β + {f}_{c} ) \qquad ( 18 )$$

in the expression:

$$\begin{matrix}{f}_{a} = \frac{2 α}{p} ( \frac{α}{2 p} + 1 ) {χ}^{2} \\ {f}_{b} = 2 [ {χ}^{2} - ( \frac{α}{p} + 1 ) χ ] \\ {f}_{c} = 1 - {χ}^{2}\end{matrix} \qquad ( 19 )$$

Given that the slots and the poles are matched, the number of slots and the number of poles are fixed, and it is specified that the external diameter of the stator is a constant, and so the stator slot area is related to only β and χ.

Further, the restrictive condition that the stator copper loss is a constant is introduced, and the copper loss is expressed as:

$${P}_{cu} = \frac{m}{2} R {\hat{I}}^{2} = \frac{1}{2} {ρ}_{cu} \frac{{L}_{cond}}{{S}_{slot} {k}_{fill}} ( {n}_{cs} {\hat{I}}^{2} ) {Q}_{s} \qquad ( 20 )$$

in the expression, ρ_{cu} is the resistivity of copper, k_{fill} is the slot fill factor, m is the number of phases, and L_{cond} is the length of a copper conductor and includes the lamination length and end winding length. In the process, the end winding length of the distributed winding may be approximately 1.5-1.7 times the pole pitch, and is 1.6 times the pole pitch herein. Therefore, L_{cond} may also be expressed as a function of the split ratio:

$${L}_{cond} = {L}_{stk} + 1.6 \frac{π {D}_{i}}{2 p} = {L}_{stk} + 2.5 \frac{{D}_{e} χ}{p} \qquad ( 21 )$$

In expression (20), except Sₛₗₒₜ, n_{cs}, and χ, the remaining parameters are all constants, therefore when the number of series turns per slot is given, the relationship between the stator slot area and the motor split ratio can be acquired:

$${S}_{slot} = \frac{{ρ}_{cu} ( {L}_{stk} + 2.5 \frac{{D}_{e} χ}{p} ) {( {n}_{cs} \hat{I} )}^{2} {Q}_{s}}{2 {P}_{cu} {k}_{fill}} \qquad ( 22 )$$

The relationship between Sₛₗₒₜ, n_{cs}, and χ of the 48-slot 8-pole synchronous reluctance motor is shown in FIG. 4. When the motor split ratio or the number of series turns per slot increases, the stator slot area also increases accordingly.

A combination of expression (18) and expression (19) results in:

$$β = \frac{- {f}_{b} - \sqrt{{f}_{b}^{2} - 4 {f}_{a} {f}_{c}^{′}}}{2 {f}_{a}} \qquad ( 23 )$$

in the expression:

$${f}_{c}^{′} = {f}_{c} - \frac{4 {Q}_{s}}{π {D}_{e}^{2}} {S}_{slot} \qquad ( 24 )$$

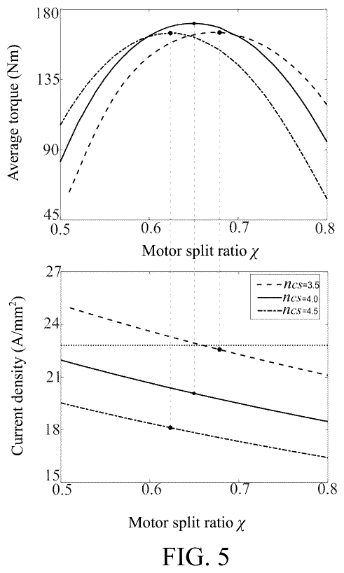

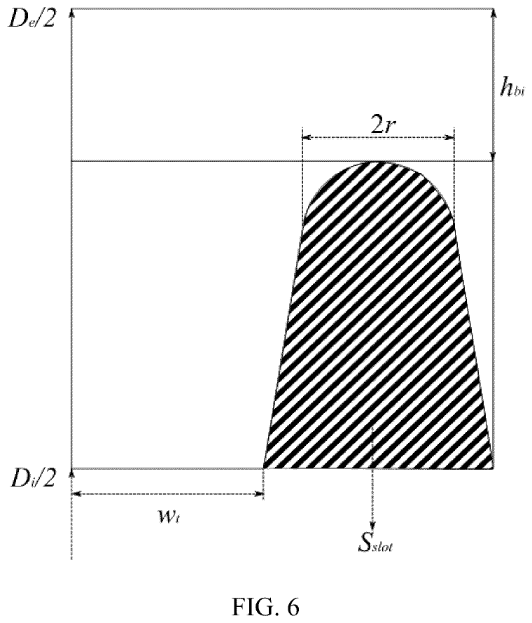

Further, the stator tooth width and the yoke thickness may be respectively expressed as functions in which the motor split ratio is the only variable by expression (14) and expression (16). When the motor split ratio is fixed, geometric parameters such as the internal diameter of the stator, the stator tooth width, the yoke thickness, etc., can all be determined. For different motor split ratios, a motor model is established, and then finite element simulation is performed to acquire average torque corresponding thereto, as is shown in the upper half of FIG. 5. Corresponding current density is shown in the lower half of FIG. 5. Obviously, for different values of the number n_{cs} of series turns per slot, different optimal values of the motor split ratio can be found by using maximum average torque as the target. In addition, considering limitations of temperature rise in the stator slot, the maximum value of the current density of a conductor is limited. In the scenario shown in the example, the maximum current density is 22.8 A/mm². When n_{cs} increases, the current density tends to increase and is at risk of exceeding the limit. In FIG. 5, the optimal motor split ratio and the number of series turns per slot are respectively 0.65 and 4, and the corresponding maximum average torque is 170.9 Nm.

The above example employs the trapezoidal slot. In order to verify the universality of the method, description is provided below by using a round-bottomed slot, as shown in FIG. 6. In this case, expression (17) is changed to:

$${S}_{slot} = \frac{π {r}^{2}}{2} + \frac{1}{2} ( 2 r + \frac{π {D}_{i} - {Q}_{s} {w}_{t}}{{Q}_{s}} ) ( \frac{{D}_{e} - {D}_{i}}{2} - {h}_{bi} - r ) \qquad ( 25 )$$

in the expression, r is the radius of the slot bottom, and in motor design, when the number of slots is determined, r is typically a constant.

Similarly, expression (14) and expression (16) are substituted into expression (25), and sorting is performed by the descending power of β to acquire:

$${S}_{slot} = \frac{π {D}_{e}^{2}}{4 {Q}_{s}} ( {f}_{a} {β}^{2} + {f}_{b} β + {f}_{c} ) \qquad ( 26 )$$

in the expression:

$$\begin{matrix}{f}_{a} = \frac{α {χ}^{2}}{p} \\ {f}_{b} = \frac{2 r {Q}_{s}}{π {D}_{e}^{2}} - χ ( 1 - χ ) - \frac{α {χ}^{2}}{p} - \frac{2 r α χ {Q}_{s}}{π {D}_{e} p} \\ {f}_{c} = χ ( 1 - χ ) + \frac{{Q}_{s}}{π {D}_{e}^{2}} [ ( 2 r - χ ) {D}_{e} + 2 π {r}^{2} - 2 r ]\end{matrix} \qquad ( 27 )$$

Given that the slots and the poles are matched, the number of slots and the number of poles are fixed, and it is specified that the external diameter of the stator is a constant, and so the stator slot area is still related to only β and x. This is consistent with the conclusion acquired from the trapezoidal slot. Therefore, the present invention is equally applicable to other slot types.

In addition, the present invention also provides a computer-readable storage medium, including a stored computer program, wherein when executed by a processor, the computer program controls a device in which the computer-readable storage medium is located to perform the above-described method for determining a tooth magnetic flux density ratio of a motor, or to perform the above-described method for determining an optimal split ratio of a motor.

It can be easily understood by those skilled in the art that the foregoing description is only preferred embodiments of the present invention and is not intended to limit the present invention. All modifications, identical replacements and improvements within the spirit and principle of the present invention should be in the scope of protection of the present invention.

1. A method for determining a tooth magnetic flux density ratio of a motor, the motor being a slotted-stator radial magnetic flux alternating current motor, and the method being characterized by comprising:
S1, under the premise that stator copper loss is fixed, acquiring a stator slot area expression in which a motor split ratio is an independent variable;
S2, acquiring a stator slot area expression in which stator yoke thickness and tooth width are independent variables, acquiring a stator yoke thickness expression in which the motor split ratio and the tooth magnetic flux density ratio are independent variables, and acquiring a tooth width expression in which the motor split ratio and the tooth magnetic flux density ratio are independent variables;
S3, substituting the stator yoke thickness expression and the tooth width expression acquired in step S2 into step S2 to acquire the stator slot area expression, and sorting by descending power according to the tooth magnetic flux density ratio, to acquire a stator slot area expression in which the motor split ratio and the tooth magnetic flux density ratio are independent variables; and
S4, when the motor split ratio is given, using an expression between a stator slot area and the motor split ratio acquired in step S1 under the condition that the stator copper loss is fixed so as to calculate a corresponding stator slot area, and then substituting the same into the stator slot area expression in which the motor split ratio and the tooth magnetic flux density ratio are independent variables acquired from step S3, to inversely acquire the tooth magnetic flux density ratio.

2. The method according to claim 1, characterized in that in step S1, the calculation formula of the stator slot area is as follows:
$${S}_{slot} = \frac{{ρ}_{Cu} ( {L}_{stk} + k \frac{π {D}_{e} χ}{2 p} ) {( {n}_{c s} \hat{I} )}^{2} {Q}_{s}}{2 {P}_{Cu} {k}_{fill}}$$
where Î represents stator phase current amplitude, n_{cs} represents the number of series turns per slot, Sₛₗₒₜ represents the stator slot area, ρcᵤ represents the resistivity of copper, Lₛₜₖ represents the length of stack lamination, k represents the ratio of the length of an end winding to pole pitch, k being 1.5-1.7 for distributed winding, and k being \sqrt{2} for fractional slot concentrated winding, Dₑ represents the external diameter of a stator, χ represents the motor split ratio, p represents the number of pole-pairs of the motor, Qₛ represents the number of stator slots, Pcᵤ represents the stator copper loss, and k_{fill} represents the slot fill factor.

3. The method according to claim 1, characterized in that the calculation formula of the tooth magnetic flux density ratio β is as follows:
$$β = \frac{- {f}_{b} - \sqrt{{f}_{b}^{2} - 4 {f}_{a} {f}_{c}}}{2 {f}_{a}}$$
$${f}_{c}^{′} = {f}_{c} - \frac{4 {Q}_{s}}{π {D}_{e}^{2}} {S}_{slot}$$
where fₐ represents a coefficient of the second power, f_{b} represents a coefficient of the first power, and f_{c} represents a constant term.

4. A method for determining an optimal split ratio of a motor, the motor being a slotted-stator radial magnetic flux alternating current motor, and the method being characterized by comprising:
S1, under the condition that different numbers of series turns per slot are given, performing analytic calculation to acquire a plurality of current density curves with a motor split ratio being an independent variable, each curve corresponding to one number of series turns per slot, and performing finite element simulation on a motor model to acquire a plurality of average torque curves with the motor split ratio being an independent variable, each curve corresponding to one number of series turns per slot;
S2, acquiring a motor split ratio corresponding to a maximum value of each average torque curve, and substituting the same into a corresponding current density curve to acquire current density at maximum average torque for the different number of series turns per slot; and
S3, acquiring a motor split ratio when maximum current density is not exceeded and the average torque is at maximum, and using the same as the optimal split ratio of the motor.

5. The method according to claim 4, characterized in that the calculation formula of current density J is as follows:
$$J = \frac{{n}_{cs} \hat{I}}{\sqrt{2} {S}_{slot} {k}_{fill}}$$
where Î represents stator phase current amplitude, n_{cs} represents the number of series turns per slot, Sₛₗₒₜ represents stator slot area, and k_{fill} represents the slot fill factor.

6. The method according to claim 4, characterized in that the average torque curve with the motor split ratio being the independent variable is acquired by the following means:
(1) the number of series turns per slot being given, acquiring a tooth magnetic flux density ratio corresponding to the number of series turns per slot;
(2) substituting the tooth magnetic flux density ratio and a given motor split ratio into a stator yoke thickness expression and a tooth width expression, to acquire a stator yoke thickness and tooth width corresponding to the motor split ratio at the number of series turns per slot;
(3) establishing a corresponding motor model according to the stator yoke thickness and tooth width corresponding to the motor split ratio at the number of series turns per slot, performing finite element simulation, and performing post-processing to acquire an average torque value corresponding to the motor model; and
(4) changing the motor split ratio, and repeating steps (2) and (3) to acquire the average torque curve with the motor split ratio being the independent variable for the number of series turns per slot.

7. The method according to claim 4, characterized in that the given different numbers of series turns per slot are determined by the following means:
(1) determining a base number of the number of series turns per slot according to motor phase voltage U:
$${n}_{cs}^{*} = \frac{Um}{\sqrt{2} π f {Q}_{s} {k}_{N 1} {Φ}_{1}}$$
where m represents the motor phase number, f represents frequency, Qₛ represents the number of stator slots, k_{N1} represents the winding factor, and Φ₁ represents magnetic flux per pole;
(2) determining the change step size of the number of series turns per slot: for a single-layer winding, the value of the change step size is 1/a, and for a double-layer winding, the value of the change step size is 2/a, where a represents the number of parallel paths of the winding; and
(3) for the base number of the number of series turns per slot, fluctuating the same according to the determined change step size, so as to determine a value range of the number of series turns per slot.

8. A computer-readable storage medium, characterized by comprising a stored computer program; when executed by a processor, the computer program controls a device in which the computer-readable storage medium is located to perform the method for determining the tooth magnetic flux density ratio of the motor according to claim 1.
